(19) United States
(12) Patent Application Publication
(10) Pub. No.: US 2026/0242976 A1
(43) Pub. Date: Aug. 20, 2026

(54) DOPED POLYCRYSTALLINE SIC WAFER WITH IMPROVED FLATNESS AND ELECTRICAL CONDUCTIVITY, AND METHOD FOR PRODUCING SUCH A WAFER

(71) Applicant: MERSEN FRANCE GENNEVILLIERS SAS, GENNEVILLIERS (FR)

(72) Inventors: Alexandre POTIER, Verneuil Sur Seine (FR); Marc FERRATO, Horgues (FR); Christophe BOMMIER, Basking Ridge, NJ (US)

(73) Assignee: MERSEN FRANCE GENNEVILLIERS SAS, GENNEVILLIERS (FR)

(21) Appl. No.: 19/159,313

(22) PCT Filed: Feb. 21, 2024
(86) PCT No.: PCT/IB2024/051644

§ 371 Date: Aug. 24, 2025

(30) Foreign Application Priority Data
Feb. 24, 2023 (FR) FR2301699

(51) Int. Cl. C30B 28/14; C30B 29/36; C30B 31/14; C30B 33/02

(52) U.S. Cl. CPC C30B 28/14; C30B 29/36; C30B 31/14; C30B 33/02

(57) ABSTRACT

A polycrystalline SiC plate having a preferential crystalline orientation, the plate having on each of its faces: its texture coefficient C₄₂₂ is less than 40%, and its texture coefficient C₂₂₀+C₂₀₀+C₄₀₀ is greater than 50%, and preferably greater than 80%. This plate can be manufactured by a CVD process. The raw blank thus obtained can be thinned by grinding and polishing. Its flatness, electrical conductivity and thermal conductivity, which are important properties for use as a substrate in microelectronics, can be improved by heat treatment.

### CROSS-REFERENCE TO RELATED APPLICATIONS

The present application is a National Stage Application of PCT International Application No. PCT/IB2024/051644 (filed on Feb. 21, 2024), under 35 U.S.C. § 371, which claims priority to French Patent Application No. FR 2301699 (filed on Feb. 24, 2023), which are each hereby incorporated by reference in their complete respective entireties.

### TECHNICAL FIELD

The invention relates to the field of materials science, and more particularly to the field of materials usable for the manufacture of substrates for integrated circuits, and processes making it possible to produce these materials. It concerns more precisely polycrystalline silicon carbide. This material, like all materials for microelectronic substrates, is used in the form of thin slices (for which the person skilled in the art often uses the English term “wafer”), which are typically circular. SiC is particularly suitable for the manufacture of substrates for use in power electronic components. SiC wafers must meet very strict specifications regarding their flatness, the homogeneity of their properties, and the absence of defects.

The present invention presents a new type of polycrystalline SiC wafers which can be used for the manufacture of substrates for integrated circuits; these wafers are made of beta-type SiC and have particular crystallographic characteristics.

Knowing that integrated circuits are generally deposited on surfaces of a monocrystalline semiconductor, in the case of a polycrystalline silicon carbide wafer, the electronically active surface (i.e. the surface on which the integrated circuits are deposited) must be specially prepared by the transfer of a monocrystalline SiC layer. This process for preparing a monocrystalline SiC layer by transfer is not part of the present invention.

The present invention also relates to a new method for manufacturing such a beta-type polycrystalline silicon carbide wafer capable of receiving, in a subsequent manufacturing step, the transfer of a monocrystalline SiC layer.

### BACKGROUND

Since the beginning of microelectronics, the vast majority of microelectronic circuits have been manufactured on a monocrystalline silicon substrate. For some specific applications, semiconductor silicon is not the ideal substrate, but it is used for lack of anything better. Silicon carbide (abbreviated SiC), for its part, is a remarkable semiconductor material: It has a wide bandgap, a high breakdown field, a high mobility of charge carriers at saturation and high thermal conductivity. This combination of exceptional physical properties gives it excellent voltage resistance, even during the passage of very high current densities, even at high temperatures. The article “SiC power components—Technology” by D. Tournier, published in 2007 as part D-3120 in the collection “Techniques de l′Ingénieur”, gives an introduction to the topic.

SiC is therefore a material perfectly suited to the manufacture of power components necessary for the efficient conversion of electrical energy in applications such as electrical power distribution, renewable energies and electric vehicles. The use of SiC makes it possible to advantageously replace silicon-based transistors such as insulated gate bipolar transistors (commonly abbreviated IGBT, Insulated Gate Bipolar Transistor) with power components such as metal-oxide gate field effect transistors. (commonly abbreviated MOSFET, Metal Oxide Semiconductor Field Effect Transistor) with a voltage withstand of the order of a kilo-Volt and much lower energy losses upon switching. In these power components, voltage resistance and temperature resistance can become limiting factors when designing electronic components and electronic cards on which these components are installed. The recent development of electric vehicles would greatly benefit from the use of such SiC power components to improve energy efficiency when converting direct current from batteries into alternating current usable by the motor. The cost and availability of these components nevertheless remain obstacles to the adoption of this technology, and for this reason silicon is still widely used as a substrate in specific applications for which SiC would present technical advantages.

According to the state of the art, the silicon carbide substrates intended to receive the deposition of microelectronic circuits take the form of wafers of generally circular shape. They are manufactured industrially using the PVT (Physical Vapor Transfer) process, which consists of sublimating a SiC powder at high temperature (>2200° C.) and condensing the vapours on a seed to obtain an ingot or “boule”» of monocrystalline SiC. From this single crystal ingot, monocrystalline SiC substrates (wafers) are then sliced. After thinning and polishing, a layer of crystalline SiC is deposited by epitaxy on one of the faces of this substrate, in order to obtain a crystal with as few defects as possible. After epitaxy, these wafers will be ready for the manufacture of electronic components.

The improvement of the industrial PVT process over the last thirty years has greatly reduced the density of the main crystalline defects in these substrates, such as dislocations and micro-pipes which strongly impacted the reliability of SiC components. In addition, it has made it possible to increase the size of the substrates (wafers) up to a diameter of 150 mm as a standard, evolving very soon towards 200 mm. Despite industrial efforts, the PVT process remains complex to master, not very productive and consuming a significant amount of energy because it requires maintaining an oven at very high temperature for around a hundred hours.

In addition, for power components, the lowest possible R_{ON} resistance in on-mode is a determining criterion for improving the energy efficiency of the system by limiting heating by the Joule effect when current passes. In these applications, the monocrystalline SiC is doped both to make it possible to manufacture the p/n junctions of the component and to reduce its resistivity in contact with the drain. The addition of nitrogen allows the substrate to be doped during crystal growth. As a standard, “n” doped wafers have a resistivity of around 20 mOhm·cm. It becomes very difficult to reduce the resistivity below this threshold without degrading the quality of the crystal, because too much doping creates stress favouring additional dislocations of the crystal.

A new technology under development would make it possible to combine the use of a low-cost SiC substrate (wafer) with improved electrical performance and a thin layer of high-quality monocrystalline SiC in which the microelectronic component would be manufactured. The monocrystalline SiC layer is attached to the substrate by a molecular bonding process as described in WO 01/18873 (Commissariat à l'Energie Atomique), which also makes it possible to guarantee a minimum contact resistance between the substrate and the transferred monocrystalline layer. Document EP 3 018 696 A1 describes an embodiment of such a process, which results in a layer of monocrystalline SiC transferred to a polycrystalline SiC substrate (denoted here “p-SiC” or “Wafer p-SiC”).

These p-SiC substrates must meet strict requirements for electrical resistance, thermal conductivity, and flatness. Today prototype “Dummy wafer” products are on the market, sold by companies such as the Ferrotec company. These standard 150 mm diameter and 750 μm thick wafers are used to balance a full charge of monocrystalline SiC wafers in certain processes to improve uniformity.

According to the state of the art, p-SiC wafers are obtained by depositing polycrystalline SiC by CVD on a cylindrical graphite substrate. The SiC obtained under these conditions is of beta type, and of 3C polytype. After having eliminated by machining the layer of SiC deposited around the periphery of the cylinder until accessing the graphite, two SiC disks can be separated from the two faces of the cylinder by oxidation in air of the graphite. This is described in patent applications JP 1994 340994 and JP 1997 296361.

However, it quickly became apparent that the disks (wafers) thus obtained presented unacceptable deformation (Bow and Warp) for the intended application. The Bow and Warp parameters represent the flatness of a wafer intended for the semiconductor industry and are known to those skilled in the art of semiconductor substrates for microelectronics (we only use the English words for these parameters, which we write here with a capital letter); they will be described in more detail below and can be measured according to the SEMI MF1390 standard. The processes described in the two Japanese documents cited above find a solution to the problem, thanks to the repetition of several stages of deposition of small thicknesses of less than 100 μm. Indeed, for a sufficiently thick deposit, the increase in grain diameter generates an internal compressive stress. The cone-shaped grains repel each other as they grow. This physical mechanism is demonstrated by P. Chaudhari in the publication “Grain growth and Stress relief in thin films”, published in Journal of Vacuum Science and Technology 9, 520 (1972), which is a basic document for any specialist in the deposition of films from a vapor phase. The process described in Japanese Patent Pub. No. JP 1994 340994 and Japanese Patent Pub. No. JP 1997 296361 makes it possible to obtain thick layers of p-SiC of several hundred microns by limiting the increase in internal compressive stresses and therefore makes it possible to limit the deformations once detached from the graphite.

Japanese Patent Pub. No. JP 3648 112 B2 describes a similar process which makes it possible to alternate the deposition of layers presenting stresses in tension and compression, in order to cancel the moment of stresses integrated over the entire thickness of the deposit. This mechanical moment is in fact at the origin of the deformation observed when the p-SiC disk is removed from its graphite substrate.

It is, however, important to note that the processes as described above are not favourable for achieving low resistivity and good thermal conductivity through the thickness of the wafer because of the multiple interfaces separating the layers in its thickness. Finding a single-layer solution to the problem would be more favourable.

U.S. Pat. No. 10,934,634 B2 describes obtaining a p-SiC wafer with excellent flatness from a monolayer of SiC deposited by CVD on a graphite substrate. A sufficiently thick deposit, typically 2 mm, has an upper part where the variation in grain diameter is stabilized. As the compressive stress no longer evolves in this part (as demonstrated in the cited publication by Chaudhari), it is then possible to extract by machining a slice with a thickness of 350 μm which presents a stress gradient and a grain size gradient in the thickness which is almost zero, and therefore to integrate an almost zero mechanical moment over the thickness. The expected effect is a very low deformation of the wafer. However, the cost and energy spent by such a process is probably unfavourable, since approximately 1.65 mm of the 2 mm layer deposited by CVD must be eliminated by grinding and polishing to obtain the wafer at the desired thickness 350 μm with the desired flatness.

To reduce manufacturing costs, it would be optimal to grow by CVD with a high deposition rate a layer of p-SiC, with a thickness as close as possible to the final thickness with a grain size very quickly stabilized after the start of growth of the layer, to avoid any unnecessary extra thickness which would become necessary to reduce or eliminate the grain size gradient.

At the Transducers & Eurosensors 2007 conference, X. A. Fu et al. published an article entitled “Nitrogen doped polycrystalline 3C-SiC films deposited by LPCVD for MEMS applications”. In this article, the authors study the deposition of SiC for levels of dopant gas (NH₃) varying from 2% to 12% in mole fraction of the silicon precursor (dichlorosilane). To obtain a resistivity below 20 mohm·cm under these conditions, the dopant level must exceed 5%. A higher dopant level leads to an increase in the residual stress without increasing the stress gradient. In this study, the deposition is carried out at low temperature 900° C. and low pressure favouring crystal growth exclusively along the (111) axis, but with an extremely slow deposition rate of 0.6 μm/h. Under these conditions, significant doping does not seem to modify the crystalline orientation of the deposited thin layer, measured by X-ray diffraction (XRD) analysis.

In the publication of H. K. E. Latha et al. published in 2014 in the journal Mater. Res. Express 1 015902, the effects of strong doping of 3C-SiC obtained by CVD using methyltrichlorosilane (MTCS) as a silicon and carbon precursor, and NH₃ as a doping agent have been studied. The deposition conditions are 1040° C. at low pressure. The growth rate of the deposited layer reaches approximately 5 μm/h, much higher than in the previous case, but still very insufficient to produce large thicknesses (several hundred microns) in an economically viable manner. An influence of the doping level on the crystal orientation and grain size is observed under these conditions. A high level of doping is accompanied by an enlargement of the grain size and their crystal orientation axis is modified according to X-ray diffraction (XRD) analysis.

Patent Application No. WO 2021/060515 (Tokai Carbon) proposes a process for obtaining a p-SiC substrate with a thickness of between 500 μm and 6 mm, at a high deposition temperature close to 1500° C. The deposition time is between 5 h and 15 h, corresponding to deposition rates above 100 μm/h, particularly suited to industrial production. Doping of p-SiC is obtained by adding dinitrogen to the mixture. To obtain a sufficiently flat substrate, the patent proposes a process which varies the concentration of SiC precursor during the deposition, in order to reduce the excessively pronounced grain size gradient in the deposited layer. This process is proposed for mass concentrations of nitrogen between 200 ppm (2.8×10¹⁹ atoms/cm³) and 1000 ppm (1.38×10²⁰ atoms/cm³). Beyond 1000 ppm, it is noted that an excessive concentration of nitrogen in p-SiC would generate significant defects in the crystals and deformation of the substrate.

Thus, a high concentration of nitrogen dopant in the p-SiC material is potentially a limiting factor for obtaining good flatness, but it is desirable for obtaining low electrical resistivity. These contradictory trends must be taken into account when seeking to manufacture a raw p-SiC substrate by CVD with low resistivity (for example <10 mOhm·cm) and sufficient flatness to be able to machine a p-SiC wafer by grinding, by removing as little thickness of material as possible. Regarding the flatness of the raw substrate obtained by CVD, one must keep in mind that the removal of material by grinding a surface as hard as that of SiC is a long and expensive process, and in addition, any thickness of material removed by grinding corresponds to material that is lost. Indeed, the cost of manufacturing the p-SiC wafer must reach a sufficiently low level to be able to serve as a combined substrate with a thin layer of monocrystalline SiC in power electronics applications.

According to the state of industrial technology, the nominal thickness of the finished p-SiC wafer is 350 μm for a nominal diameter of 150 mm. A thicker raw product (blank) is made from a CVD deposition process on a graphite substrate. For economic reasons, once detached from the graphite, the p-SiC blank must not exceed a thickness of 1 mm; typically 750 μm and preferably 600 μm are aimed, in order to obtain a reasonable CVD deposition time and to reduce the thickness to be eliminated by grinding and polishing, to respectively a maximum of 650 μm, typically 400 μm, preferably 250 μm. It should be noted in this context that one would generally like to minimize the thickness of material which must be removed by grinding, knowing that SiC results from a high temperature manufacturing process, and is one of the hardest materials known, after diamond.

The Warp of a 350 μm thick wafer with a six-inch diameter must be less than 50 μm after grinding and polishing to comply with microelectronics standards. To achieve this objective, it is first necessary to prepare by grinding from the raw blank removed from the graphite an intermediate blank, which will then serve as a starting point to prepare, by fine grinding followed by polishing, the wafer of p-SiC onto which a monocrystalline layer of SiC will then be transferred. The difference between the initial thickness of the raw blank and the deformation measured on said raw blank must not be less than the thickness of the intermediate blank. This means that the volume of the ground intermediate (cylindrical) blank must be included in the volume of the raw blank (see FIG. 1).

### SUMMARY

In the present invention, the inventors have sought to optimize the manufacture of a polycrystalline SiC plate having a high level of dopant (for example n-type, such as nitrogen or phosphorus) typically greater than 5×10¹⁹ atoms/cm³, preferably greater than 10²⁰ atoms/cm³, to typically achieve a resistivity of the material less than 15 mOhm·cm and preferably less than 10 mOhm·cm. The thermal conductivity of the material should typically be greater than 200 W/m/K, but a value greater than 250 W/m/K is preferred, despite a high level of N dopant which can affect the thermal conductivity by generating additional crystalline defects harmful to the propagation of phonons. One is also looking for a polycrystalline SiC plate which has excellent surface homogeneity of its grain size, and preferably a fine grain.

It results from the work carried out by the inventors of the present application that a massive plate of polycrystalline SiC (denoted here “p-SiC”) of beta type can be obtained by chemical vapor deposition (CVD) operating in a range of temperature ranging from approximately 1 300 K to approximately 1 800 K on a substrate comprising a graphite surface. In this process, a mixture of gases is introduced into a heated enclosure so as to create a gas phase comprising at least one gaseous precursor of silicon and/or carbon, at least one doping gas comprising at least one doping atom, such as nitrogen and/or phosphorus, and a carrier gas, said mixture of gases decomposing on the surface of said graphite substrate to form a layer of beta-type polycrystalline SiC on said graphite surface of said substrate, and said method being characterized in that that the temperature in the reactor is between 1 450 K and 1 650 K and the total partial pressure of said gaseous precursors is less than 350 mbar, and preferably less than 300 mbar. This deposition is done on the graphite surface of a substrate comprising a graphite surface; said substrate may be a graphite plate. This substrate, and more particularly this graphite plate, is advantageously circular, so as to allow the direct production of a circular SiC disk.

According to an advantageous embodiment of this deposition process, said gas phase comprises trichloromethylsilane as a silicon and carbon precursor. Said doping gas is advantageously selected from the group formed by: NH₃, N₂H₄, N₂, H₂NCH₃.

This process makes it possible to deposit a layer of polycrystalline silicon carbide (p-SiC) which can then be separated from the graphite surface on which it has been formed; a p-SiC plate is thus obtained whose thickness can be reduced by grinding followed by polishing of both sides.

Thus a polycrystalline SiC plate can be produced. This plate can be a raw blank, which can then undergo grinding steps to become an intermediate blank for the manufacture of a polycrystalline SiC substrate (wafer) capable of receiving a transfer of a monocrystalline SiC layer to form a wafer usable for the manufacture of a substrate for the deposition of integrated circuits. Said plate, said raw blank and said intermediate blank represent objects of the present invention, as will be explained subsequently. They advantageously have a particular microstructure and crystallographic texture, as will be explained below.

In a typical embodiment, the plate according to the invention undergoes material removal on one and/or the other of these two faces before presenting the properties described.

A first object of the present invention is a beta-type polycrystalline SiC plate having a preferential crystalline orientation, said plate being characterized in that on each of its faces: (i) its texture coefficient C₄₂₂ is less than 40%, and (ii) its texture coefficient C₂₂₀+C₂₀₀+C₄₀₀ is greater than 50%, and preferably greater than 80%.

According to a first aspect of this first object of the invention, its electrical resistivity is less than 10 mOhm·cm, preferably less than 5 mOhm·cm, and even more preferably less than 3 mOhm·cm.

According to a second aspect of this first object of the invention, which can be combined with the first aspect, said plate is doped with nitrogen with a nitrogen level, measured by secondary ion mass spectroscopy (SIMS, Secondary Ion Mass Spectroscopy), greater than 5×10¹⁹ atoms/cm³, preferably greater than 1×10²⁰ atoms/cm³, and even more preferably greater than 1.5×10²⁰ atoms/cm³.

According to a third aspect of this first object of the invention, which can be combined with the first and/or the second aspect, said plate is doped with phosphorus with a phosphorus level, measured by secondary ion mass spectroscopy, greater than 5×10¹⁹ atoms/cm³, preferably greater than 1×10²⁰ atoms/cm³, and even more preferably greater than 1.5×10²⁰ atoms/cm³.

According to a fourth aspect of this first object of the invention, which can be combined with the first and/or the second and/or the third aspect, on each of the two faces of said plate its texture coefficient C₄₂₂ is less than 20%, preferably less than 15%, and even more preferably less than 10%.

According to a fifth aspect of this first object of the invention, which can be combined with the first and/or the second and/or the third and/or the fourth aspect, said plate is doped with nitrogen with a level of nitrogen or phosphorus, measured by mass spectroscopy of secondary ions, greater than 5×10¹⁹ atoms/cm³, said plate having an electrical resistivity less than 5 mOhm·cm and a preferential crystalline orientation, and said plate being characterized in that on each of its two faces: (i) its texture coefficient C₄₂₂ is less than 20%, and (ii) its texture coefficient C₂₂₀+C₂₀₀+C₄₀₀ is greater than 60%, and preferably greater than 80%.

According to a sixth aspect of this first object of the invention, which can be combined with the first and/or the second and/or the third and/or the fourth and/or with the fifth aspect, said plate is a raw blank resulting from of a vapor deposition process, which has undergone at least one heat treatment step at a temperature between 1,800° C. and 2,300° C., preferably between 1 850° C. and 2 200° C., more preferably between 1 900° C. and 2,150° C., and even more preferably between 1 950° C. and 2 150° C., knowing that, before or after said heat treatment, a material thickness of at least 100 μm has been removed from said raw blank, at least on its face which was in contact with a growth substrate, and knowing that preferably, during this heat treatment said plate is held flat on a flat surface.

According to a seventh aspect of this first object of the invention, which can be combined with the first and/or the second and/or the third and/or the fourth and/or with the fifth and/or with the sixth aspect, said plate is an intermediate blank for the manufacture of a wafer obtained by rectification of a raw blank according to the sixth aspect of this first object.

According to an eighth aspect of this first object of the invention, which can be combined with the first and/or the second and/or the third and/or the fourth and/or with the fifth and/or with the sixth and/or with the seventh aspect, the thickness of said plate is less than 550 μm, preferably less than 500 μm, more preferably less than 450 μm, and even more preferably between 355 μm and 420 μm.

According to a ninth aspect of this first object of the invention, which can be combined with the first and/or the second and/or the third and/or the fourth and/or with the fifth and/or with the sixth and/or with the seventh and/or with the eighth aspect, said plate has a diameter of between 140 mm and 165 mm, a thickness of between 350 μm and 450 μm and a deformation characterized by a Warp of less than 100 μm, preferably less than 50 μm and even more preferably less than 30 μm.

According to a tenth aspect of this first object of the invention, which can be combined with the first and/or the second and/or the third and/or the fourth and/or with the fifth and/or with the sixth and/or with the seventh and/or with the eighth and/or with the ninth aspect, said plate has a thickness of between 350 μm and 400 μm.

According to an eleventh aspect of this first object of the invention, which can be combined with the first and/or the second and/or the third and/or the fourth and/or with the fifth and/or with the sixth and/or with the seventh and/or with the eighth and/or with the ninth and/or with the tenth aspect, said plate has a diameter of between 185 mm and 210 mm, and a thickness of between 500 μm and 650 μm, preferably of between 500 μm and 600 μm.

According to a twelfth aspect of this first object of the invention, which can be combined with the first and/or the second and/or the third and/or the fourth and/or with the fifth and/or with the sixth and/or with the seventh and/or with the eighth and/or with the ninth and/or with the tenth and/or with the eleventh aspect, said plate has a deformation characterized by a Warp of less than 70 μm, preferably less than 50 μm and even more preferably less than 40 μm.

According to a thirteenth aspect of this first object of the invention, which can be combined with the first and/or the second and/or the third and/or the fourth and/or with the fifth and/or with the sixth and/or with the seventh and/or with the eighth and/or with the ninth and/or with the tenth and/or with the eleventh and/or with the twelfth aspect, on each of the two faces of said plate, the contribution C₂₀₀+C₄₀₀ is greater than 1%, more preferably greater than 2%, and even more preferably greater than 5%.

According to a fourteenth aspect of this first object of the invention, which can be combined with the first and/or the second and/or the third and/or the fourth and/or with the fifth and/or with the sixth and/or or with the seventh and/or with the eighth and/or with the ninth and/or with the tenth and/or with the eleventh and/or with the twelfth and/or with the thirteenth aspect, said plate has a thermal conductivity greater than 250 W/(m·K), preferably greater than 260 W/(m·K), and more preferably greater than 270 W/(m·K).

According to a fifteenth aspect of this first object of the invention, which can be combined with the first and/or the second and/or the third and/or the fourth and/or with the fifth and/or with the sixth and/or with the seventh and/or with the eighth and/or with the ninth and/or with the tenth and/or with the eleventh and/or with the twelfth and/or with the thirteenth and/or with the fourteenth aspect, said plate has was obtained by a CVD process.

According to a sixteenth aspect of this first object of the invention, which can be combined with the first and/or the second and/or the third and/or the fourth and/or with the fifth and/or with the sixth and/or with the seventh and/or with the eighth and/or with the ninth and/or with the tenth and/or with the eleventh and/or with the twelfth and/or with the thirteenth and/or with the fourteenth and/or with the fifteenth aspect, said plate is characterized by:
an electrical resistivity less than 5 mOhm·cm, and preferably less than 3 mOhm·cm,
a doping level, measured by SIMS, which is greater than 1×10²⁰ atoms/cm³, and more preferably greater than 1.5×10²⁰ atoms/cm³,
on each of its two faces, a texture coefficient C₂₂₀+C₂₀₀+C₄₀₀ greater than 60%, and preferably greater than 80%,
on each of its two faces, a texture coefficient C₄₂₂ less than 15%, and preferably less than 10%,
on each of its two sides, a C₂₀₀+C₄₀₀ contribution greater than 2%, and preferably greater than 5%, and
a thermal conductivity greater than 260 W/(m·K), preferably greater than 270 W/(m·K).

According to a seventeenth aspect of this first object of the invention, which can be combined with the first and/or the second and/or the third and/or the fourth and/or with the fifth and/or with the sixth and/or with the seventh and/or with the eighth and/or with the ninth and/or with the tenth and/or with the eleventh and/or with the twelfth and/or with the thirteenth and/or with the fourteenth and/or with the fifteenth and/or with the sixteenth aspect, said plate is characterized by:
an electrical resistivity less than 5 mOhm·cm, and preferably less than 3 mOhm·cm,
a doping level, measured by SIMS, greater than 1×10²⁰ atoms/cm³, and even preferably greater than 1.5×10²⁰ atoms/cm³,
on each of its two faces, a texture coefficient C₂₂₀+C₂₀₀+C₄₀₀ greater than 80%,
on each of its two faces, a texture coefficient C₄₂₂ less than 15%, and preferably less than 10%,
on each of its two sides, a C₂₀₀+C₄₀₀ contribution greater than 5%,
a thermal conductivity greater than 260 W/(m·K), preferably greater than 270 W/(m·K).

According to an eighteenth aspect of this first object of the invention, which can be combined with the first and/or the second and/or the third and/or the fourth and/or with the fifth and/or with the sixth and/or with the seventh and/or with the eighth and/or with the ninth and/or with the tenth and/or with the eleventh and/or with the twelfth and/or with the thirteenth and/or with the fourteenth and/or with the fifteenth and/or with the sixteenth aspect and/or with said seventeenth aspect, said plate is characterized by the fact that it has undergone material removal on one and/or the other of these two faces before presenting at least one of the characteristics or properties according to the first object of the invention or any one of its eighteen aspects.

A second object of the invention is a method of manufacturing a beta-type polycrystalline SiC plate comprising a step of chemical vapor deposition of a layer of polycrystalline SiC on the graphite surface of a substrate comprising a surface in graphite, in which a mixture of gases is introduced into a heated enclosure so as to create a gas phase comprising:
at least one gaseous silicon and/or carbon precursor,
at least one doping gas comprising at least one nitrogen and/or phosphorus atom,
a carrier gas, said mixture of gases decomposing on the surface of said graphite substrate to form a layer of polycrystalline SiC on said graphite surface of said substrate,
and said method being characterized in that:
the temperature in said heated enclosure is between 1 450 K and 1 650 K and the total partial pressure of said gaseous precursors is less than 350 mbar, and preferably less than 300 mbar, and
the chemical vapor deposition step is followed by at least heat treatment step of said layer of polycrystalline SiC, at a temperature between 1 800° C. and 2 300° C., preferably between 1 850° C. and 2 200° C., more preferably between 1 900° C. and 2 150° C., and even more preferably between 1 950° C. and 2 150° C.

According to a first aspect of this second object of the invention, said process is characterized in that the temperature in said heated enclosure is between 1 450 K and 1 650 K and the total partial pressure of said gaseous precursors is less than 300 mbar.

According to a second aspect of this second object of the invention, which can be combined with the first aspect, the chemical vapor deposition step is followed by at least heat treatment step of said polycrystalline SiC plate, at a temperature between 1 900° C. and 2 150° C.

According to a third aspect of this second object of the invention, which can be combined with the first and/or the second aspect, said heat treatment is carried out at a temperature between 1 950° C. and 2 150° C.

According to a fourth aspect of this second object of the invention, which can be combined with the first and/or the second and/or the third aspect, said doping gas is selected from the group formed by: NH₃, N₂H₄, N₂, H₂NCH₃.

According to a fifth aspect of this second object of the invention, which can be combined with the first and/or the second and/or with the third and/or with the fourth aspect, said doping gas is present in said enclosure heated in one concentration selected so as to lead in said polycrystalline SiC plate to a level of nitrogen or phosphorus, measured by secondary ion mass spectroscopy, greater than 5×10¹⁹ atoms/cm³, preferably greater than 1×10²⁰ atoms/cm³, and even more preferably greater than 1.5×10²⁰ atoms/cm³.

According to a sixth aspect of this second object of the invention, which can be combined with the first and/or the second and/or the third and/or the fourth and/or the fifth aspect, during this heat treatment, the plate or the raw blank is held flat on a flat surface.

According to a seventh aspect of this second object of the invention, which can be combined with the first and/or the second and/or the third and/or the fourth and/or the fifth and/or the sixth aspect, said raw blank or plate has been cleared, before or after said heat treatment, at least on its side which was in contact with a growth substrate, with a material thickness of at least 100 μm.

According to an eighth aspect of this second object of the invention, a SiC plate having been manufactured by the chemical vapor deposition process according to the second object of the invention is provided, or such a plate is manufactured by said chemical vapor deposition process, said supplied or manufactured plate having, on each of its two faces, possibly measured after removal of a thickness of material of at least 100 μm, a texture coefficient C₄₂₂ less than 30% and a coefficient of texture C₂₂₀ greater than 60%, and said heat treatment is carried out according to the second object of the invention, knowing that this eighth aspect of this second object of the invention can be combined with the first and/or the second and/or the third and/or the fourth and/or the fifth aspect and/or the sixth aspect and/or the seventh aspect of this second object of the invention.

### DRAWINGS

Figures illustrate different aspects of the invention.

FIG. 1 schematically shows the measurement of the parameter called “Warp” which expresses a particular aspect of the flatness defect of a semiconductor wafer.

FIG. 2 shows in a schematic and simplified manner a vertical cross section through a reactor according to the invention which makes it possible to manufacture a blank for a polycrystalline SiC substrate according to the invention.

FIG. 3 refers to Example 1 and shows an image obtained by scanning electron microscopy of backscattered electrons of a cross section of a p-SiC plate obtained by a CVD process outside the invention, before heat treatment at 2000° C. The white bar at the bottom right indicates a length of 100 μm.

FIG. 4 refers to Example 1 and shows an image obtained by scanning electron microscopy of backscattered electrons of a cross section of a p-SiC plate obtained by a CVD process outside the invention, after a heat treatment at 2 000° C. The white bar at the bottom right indicates a length of 100 μm. The sample comes from a p-SiC plate obtained at the same time (same reactor, same experimental conditions, same test) as that from which the sample in FIG. 3 was obtained.

FIG. 5 refers to Example 2 and shows an image obtained by scanning electron microscopy of backscattered electrons of a cross section of a p-SiC plate obtained by a CVD process outside the invention, before a heat treatment at 2 000° C. The white bar at the bottom right indicates a length of 100 μm.

FIG. 6 refers to Example 2 and shows an image obtained by scanning electron microscopy of backscattered electrons of a cross section of a p-SiC plate obtained by a CVD process outside the invention, after a heat treatment at 2 000° C. The white bar at the bottom right indicates a length of 100 μm. The sample comes from a p-SiC plate obtained at the same time (same reactor, same experimental conditions, same test) as that from which the sample in FIG. 5 was obtained.

FIG. 7 refers to Example 3 and shows an image obtained by scanning electron microscopy of backscattered electrons of a cross section of a p-SiC plate obtained by a CVD process according to the invention, before heat treatment at 2 000° C. The white bar at the bottom right indicates a length of 100 μm.

FIG. 8 refers to Example 3 and shows an image obtained by scanning electron microscopy of backscattered electrons of a cross section of a p-SiC plate obtained by a CVD process outside the invention, after a heat treatment at 2 000° C. The white bar at the bottom right indicates a length of 100 μm. The sample comes from a p-SiC plate obtained at the same time (same reactor, same experimental conditions, same test) as that from which the sample in FIG. 7 was obtained.

FIGS. 9a to 9f show a diffractogram obtained with X-ray radiation of wavelength 1.5406 Angstrom on a beta-type polycrystalline SiC plate obtained according to the invention by the CVD process, before heat treatment. FIGS. 9a to 9f show different areas of angle 2theta, and the scale of the vertical axis may differ from one figure to another, to make appear low intensity peaks.

FIGS. 10a to 10e show the same type of diffractogram as FIGS. 9a to 9f, for the same plate as that of FIGS. 9a to 9f, but after heat treatment according to the invention.

### DESCRIPTION

The term “plate” must be understood here in its broadest sense, which includes in particular the objects designated below as “raw blank”, “heat-treated raw blank”, “intermediate blank” and “wafer”. These objects are generally flat in shape.

Those skilled in the art of semiconductor substrates for microelectronics know the different ways to characterize the overall flatness of wafers: these different parameters are known under the terms or acronyms Bow (the distance between the surface and the plane corresponding to the best fit at the centre of the unfixed wafer, see standard ASTM F534 “Standard Test Method for Bow of Silicon Wafers” point 3.1.2), Warp (the sum of the maximum positive and negative deviations from the plane corresponding to the best fit for an unfixed wafer, see standard ASTM F1390 “Standard test Method for Measuring Warp on Silicon Wafers by Automated Non-Contact Scanning”), TTV (Total Thickness Variation, i.e. the difference between the maximum and minimum thickness values for a fixed wafer, see the standard ASTM F657 “Standard Test Method for Measuring Warp and Total Thickness Variation on Silicon Slices and Wafers by a Non-contact Scanning Method”), TIR (Total Indicated Reading, i.e. the sum of the maximum positive and negative deviations from the plane corresponding to the best adjustment for a fixed wafer), SRAD (Spherical Reference Measurement, expressing a radius of curvature for the sphere corresponding to the best fit); other acronyms express parameters to characterize the local flatness of wafers, in particular: LFPD (Local Focal Plane Deviation, i.e. the maximum distance between the surface of the wafer and the plane corresponding to the best fit (above or below the surface of the unfixed wafer), for a given area) and LTV (Local Thickness Variation, i.e. the difference between the maximum and minimum thickness values of the unfixed wafer, for a given area).

In the context of the present invention, the flatness of the wafers is characterized by the parameter commonly called “Warp”. This parameter refers to the algebraic difference of the deviations of the wafer relative to a reference plane. FIG. 1 schematically illustrates the determination of this parameter from a surface profile by the algebraic difference of the ordinates B and C of the disk placed on a base plane.

One could also determine a median plane from the profile of the surface (typically by using an algorithm implementing a least squares method) and calculate the Warp from the deviations from the median plane, which gives the same result provided that the median plane is parallel to the base plane. If the median plane is not parallel to the base plane, then the measurement method relative to the base plane increases that relative to the median plane.

We now describe a new process for depositing a raw blank of beta-type p-SiC which contributes to the solution of the problem posed.

This deposition process represents the first step of a process for manufacturing a polycrystalline SiC plate according to the invention. It uses the chemical vapor deposition (CVD) technique, which is carried out in a heated chamber. The process involves a gas mixture comprising at least one silicon precursor gas (such as a silane or a chlorosilane) and/or at least one carbon precursor gas (such as an alkane or an alkene), and/or at least one silicon and carbon precursor gas (such as methyltrichlorosilane, abbreviated MTCS), and at least one doping gas comprising nitrogen (for example NH₃, N₂H₄, N₂) and/or phosphorus. Said doping gas can also be a carbon and/or silicon precursor (for example an amine such as H₂NCH₃). These gases can be diluted in a carrier gas, which can be a reducing gas such as hydrogen and/or an inert gas such as argon.

By way of example, a gaseous composition for implementing the process according to the invention may comprise a carbon precursor, a silicon precursor, a doping gas, the carrier gas. Another example is a gaseous composition which includes a silicon and carbon precursor, a silicon precursor, a carbon precursor, a doping gas, the carrier gas.

In a particular embodiment of this deposition process, said gas phase comprises trichloromethylsilane, and preferably does not comprise any other silicon and/or carbon precursors. Said doping gas is advantageously selected from the group formed by: NH₃, N₂H₄, N₂, H₂NCH₃.

This gas mixture is admitted into a reactor held at high temperature where the precursor gases are decomposed and react on the surface to form the 3C-SiC polytype. This material is particularly suitable to be combined with a layer of monocrystalline SiC, due to its mechanical and thermal resistance properties, its compatibility in thermal expansion and its purity. It can also be doped with nitrogen up to very high levels, typically 10²⁰ atoms/cm³ and have a resistivity much lower than 20 Ohm·cm, without degradation of the quality of the substrate which would be detrimental to the manufacture of power components. Finally, it is a material capable of subsequently resisting the high temperature processes that the wafer will have to undergo during the manufacturing of the electronic component.

The reactor temperature during CVD deposition of SiC must be between approximately 1300 K and approximately 1800 K, and preferably between approximately 1350 K and approximately 1700 K, more preferably between approximately 1400 K and approximately 1650 K. K, and even more preferably between approximately 1450 K and approximately 1650 K. The total pressure in the reactor advantageously does not exceed 350 mbar, and preferably does not exceed 300 mbar.

In an advantageous embodiment of the process for manufacturing the p-SiC plate according to the invention, deposition is carried out by the CVD route on a graphite surface of a substrate comprising a graphite surface. Very advantageously, said substrate is a fine-grained and purified isostatic graphite substrate, such as to avoid any contamination and degassing of impurities during deposition. For example, to obtain a wafer with a diameter of 150 mm, the deposition is carried out on a disc-shaped graphite cylinder, with a diameter approaching a nominal of 150 mm and a thickness greater than 2 mm to ensure sufficient flatness of the substrate. The reactor may include a plurality of these disks, the diameter of which may be identical or different. The two faces of the discs preferably have a flatness <15 μm, obtained by sufficiently precise machining. The thermal expansion coefficient of isostatic graphite is chosen judiciously to be compatible with the SiC layer during cooling after deposition. A substrate marketed by the company MERSEN under the designation “grade 2303” can be used.

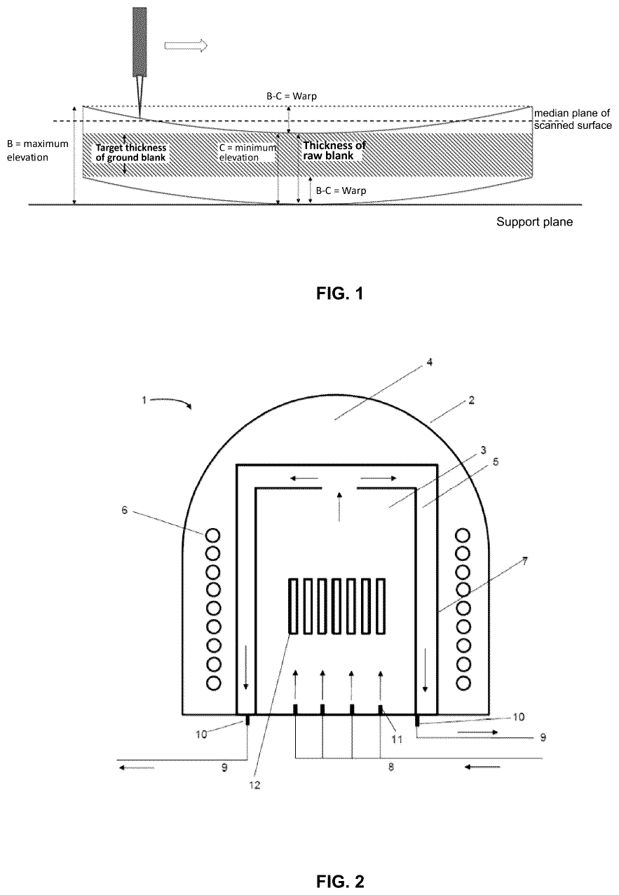

We now describe the progress of a typical embodiment of this process for depositing a raw blank which can be used to produce a p-SiC plate according to the invention, and we first describe in relation to FIG. 2, by way of example, a reactor in which this deposition process can be carried out. This deposition process takes place in a reactor 1 of a particular type. It comprises a reaction enclosure 2, which contains a reaction space 3, a heating space 4 and a space 5 for the evacuation of the reaction gases. Said enclosure 2 is designed to be able to reach low pressures up to a minimum of a few tens of milli-bar by pumping gases to an effluent treatment device (not shown in the figure). The precursor gases are admitted into the reaction space 3 of the reactor 1 through a plurality of injectors 11 supplied by a gas line 8 called the precursor gas inlet. The reaction gases leave the reaction space 3 towards the evacuation space 5, from where they are sucked through an outlet nozzle 10 into the gas line 9 called the reaction gas outlet. The heating space 4 comprises a plurality of heating elements 6, typically solenoids. Graphite cylinders or disks 12, also called substrates here, are loaded into enclosure 2; to simplify, FIG. 2 does not show the supports which hold said substrates 12 in the reactor 1.

The reaction enclosure 2 is heated by induction of a magnetic field in a graphite susceptor 7 inside which the precursor gases (for example silanes, alkanes and/or methyl-chlorosilanes), the carrier gases (for example hydrogen and/or argon), the doping gas (for example NH₃, amines and/or N₂) will circulate. The graphite substrates 12 are in thermal equilibrium inside the reaction space 3 heated by the susceptor 7 to a temperature generally between 1 300 K and 1 700 K (measured by a thermocouple), and more preferably between 1 350 K and 1 650 K. The gas mixture is introduced by nozzles or injectors 11 allowing a homogeneous distribution of the gas flow in the enclosure 2. In this temperature range, the deposition rates can vary in fairly wide ranges, from μm/h to more than 100 μm/h. The total partial pressure of said gaseous precursors is advantageously less than 350 mbar, and preferably less than 300 mbar.

To achieve a minimum p-SiC deposit thickness of around 600 μm, the gas injection time can vary from a few hours to several tens, or even hundreds of hours depending on the conditions chosen. The control parameters indicated above can be adjusted to obtain the product according to the invention, as will be explained in greater detail in relation with the examples. It is thus possible to obtain high quality p-SiC wafers under economically satisfactory conditions, allowing them to be used in electronic applications substituting monocrystalline SiC produced by the traditional PVT process.

When the target thickness for the deposit on the surface of the graphite substrate 12 is reached, the injection of the precursor gases into the oven is stopped and the enclosure is cooled to ambient temperature to be unloaded. The graphite discs 12 coated with a thick layer of SiC deposit are then machined, then oxidized in air, typically at 900° C., to eliminate any graphite residue. A disk of raw SiC is recovered for each side.

The deformation of the disc, the raw blank, is measured using a white light confocal sensor which scans the surface of the SiC disc which was in contact with the graphite. To carry out this measurement, the side of the disc on the CVD deposition side is placed on a support. The difference between the maximum and minimum elevation of the surface scanned by the sensor in relation to the support plane of the measuring tool is measured. The graphite side surface was a plane reference before being detached from the graphite. After detachment of the graphite, this surface becomes deformed due to the relaxation of the stresses of the deposited layer. This deformed surface can be interpolated by a median plane, using the least squares method. If this median plane is parallel to the support plane, the deformation measurement is equal to the Warp. This method of measuring deformation increases the Warp measurement in the general case.

The raw blank resulting from the deposition process which has just been described presents (possibly after having been removed, at least on its side which was in contact with the growth substrate, a material thickness of approximately 100 μm or more), particular crystallographic characteristics, namely a preferential crystalline orientation which is characterized on each of its two faces by: (i) its texture coefficient C₄₂₂ is less than 40%, and (ii) its texture coefficient C₂₂₀ is greater than 50%, and preferably greater than 80%.

Preferably, its texture coefficient C₄₂₂ is less than 30% and its texture coefficient C₂₂₀ is greater than 70%. Even more preferably, its texture coefficient C₄₂₂ is less than 30% and its texture coefficient C₂₂₀ is greater than 80%.

As it has just be seen, the process for manufacturing a p-SiC plate according to the invention comprises a first step in which silicon carbide is deposited from a vapor phase on the graphite surface of a substrate having a graphite surface, to obtain a raw blank of polycrystalline silicon carbide (abbreviated here “p-SiC”), having a first thickness.

According to an essential characteristic of the invention, this raw blank is subjected to a specific heat treatment. The heat treatment process according to the invention is described here.

In a second step, said raw blank is subjected to a heat treatment of between 1 800° C. and 2 300° C., to obtain a heat-treated raw blank; this is always polycrystalline silicon carbide. During this heat treatment, the raw blank is advantageously kept flat on a flat surface.

In a third step, said heat-treated raw blank is subjected to a grinding treatment on both sides, to obtain an intermediate polycrystalline silicon carbide blank of a second thickness. This processing by grinding takes place in several sub-steps; is known as such.

The second step and the third step may be interchanged, and the heat treatment may also be carried out on a partially ground blank, such that the third step is carried out partly before the second step and partly after the second step.

This intermediate blank can be transformed by various polishing steps (which will possibly be preceded by one or more fine grinding steps) into a wafer of polycrystalline SiC ready to receive a deposit of a thin layer of monocrystalline silicon carbide (called here “m-SiC”), in particular by layer transfer techniques. These polishing steps and this deposition of a thin layer of m-SiC are known as such and are not part of the present invention.

According to an essential technical characteristic of the invention, the blank, which can be a raw blank or an intermediate blank, is subjected to a specific heat treatment, which was identified above as the “second step” of the process according to the invention, and which will now be described in greater detail. This specific heat treatment leads to a specific modification of the size of the grains and their crystallographic orientation, which is only observed in the case where the raw or intermediate p-SiC blank presents certain specific crystallographic characteristics. More particularly, this heat treatment is carried out at a temperature between 1 800° C. and 2 300° C., preferably between 1 850° C. and 2 200° C., more preferably between 1 900° C. and 2 150° C., and even more preferably between 1 950° C. and 2 150° C. Its duration is advantageously at least 10 minutes and is advantageously between approximately 1 hour and approximately 12 hours, and preferably between approximately 2 hours and approximately 9 hours. A duration that is too long can lead to unwanted recrystallization; with a duration that is too short, the heat treatment may be ineffective. Typically, to carry out this heat treatment, the blank is loaded into an oven at room or lukewarm temperature, and the oven is heated to the desired temperature, then it is maintained at this temperature, and finally it is left to cool, to unload the oven at room temperature or lukewarm; the treatment times indicated then relate to the temperature zone indicated, and not to the total duration of the thermal cycle.

By means of this specific heat treatment, it is possible to obtain a raw blank or an intermediate blank in heat-treated beta-type p-SiC which has favourable crystallographic characteristics. More precisely, the raw or intermediate heat-treated p-SiC blank has a preferential crystalline orientation which is characterized in that on each of its faces: (i) its texture coefficient C₄₂₂ is less than 40%, and (ii) its texture coefficient C₂₂₀+C₂₀₀+C₄₀₀ is greater than 50%, and preferably greater than 80%.

Preferably, the contribution C₂₀₀+C₄₀₀ is greater than 1%, more preferably greater than 2%, and even more preferably greater than 5%. It is this C₂₀₀+C₄₀₀ contribution to the crystallographic orientation characterized by a very dominant C₂₂₀ texture which is generated by the heat treatment to which the raw blank is subjected in said second step.

Advantageously, after this heat treatment called here “second step”, said raw or intermediate blank has on each of its two faces a texture coefficient C₄₂₂ which is less than 20%, preferably less than 15%, and even more preferably less than 10%. It may for example be a raw blank which has been removed, before or after said heat treatment, at least on its side which was in contact with a growth substrate, with a material thickness of at least 100 μm.

Generally speaking, the heat treatment indicated above does not lead to the appearance of an alpha phase. Without wishing to be bound by this hypothesis, the inventors believe that in the case of doped SiC, it is the presence of doping elements which blocks the transformation of beta-type polycrystalline SiC into alpha-type polycrystalline SiC.

The applicant has noted that the heat treatment indicated above only leads to a raw blank having these favourable crystallographic characteristics on both sides in the case where the raw or intermediate blank before heat treatment presented certain specific crystallographic characteristics, namely, on at least one of its faces, (i) a texture coefficient C₄₂₂ which is less than 30%, and (ii) a texture coefficient C₂₂₀ which is greater than 60%, and preferably greater than 80%.

The heat treatment of such a blank first leads to a rearrangement of crystallographic defects at the grain boundaries (which leads to the relaxation of residual stresses at the grain boundaries), then to recrystallization by nucleation at the grain boundaries, followed by a growth of these grains. Thus, the initial grain size can influence the microstructure obtained at the end of the heat treatment. The inventors have found that this is, however, not sufficient to explain the difference in behaviour between samples whose physical properties and flatness improve during heat treatment and those which do not show significant improvement. It is also the nature of the crystallographic defects which is decisive: to facilitate recrystallization which effectively relaxes the stresses, the small grains must be bordered by grain boundaries with strong misorientation (known by the acronym HAGB—High Angle Grain Boundaries). These highly misorientated grain boundaries contain particularly large stored energy, and are therefore more mobile than low misorientation grain boundaries. Their internal energy is the driving force for the rearrangement of defects at grain boundaries. In the process according to the invention, it is the particular texture of the blank subjected to the heat treatment which ensures the presence of such grain boundaries with strong misorientation.

Empirically, the grains can have an average diameter (measured in a plane perpendicular to the z axis, for example by EBSD) greater than or equal to 5 μm, in particular greater than or equal to 10 μm, or even 20 μm or 50 μm in certain cases support substrates 20 after the aforementioned heat treatment. In particular, the grains having (200) and (400) orientation have an average diameter greater than or equal to 5 μm, in particular greater than or equal to 10 μm, or even 20 μm or 50 μm, as a result of the heat treatment which causes coalescence and recrystallization of certain orientation grains (220).

When measuring the average diameter of a grain, it is considered that different crystals forming one or more twins constitute the same grain and not distinct grains. Thus, the size of the grains tends to increase during the heat treatment, their average diameter being able to be multiplied at least by 2, frequently by 5 or even by 10 or 50, depending on the conditions and the duration of the heat treatment. This is particularly the case for the (220) orientation grains, which appear to have a greater tendency to coalescence and recrystallization than the (422) grains in particular.

Thus, raw discs whose microstructure has a texture coefficient C₄₂₂ less than 40% and a sum of texture coefficients C₂₂₀+C₂₀₀+C₄₀₀ greater than 50% turn out to be particularly sensitive to heat treatments. However, the increase in grain size during heat treatment is correlated with an increase in thermal conductivity, which therefore makes it possible to achieve high thermal conductivity values, which are preferably greater than 250 W/(m·K), more preferably greater than 260 W/(m·K), and even more preferably greater than 270 W/(m·K).

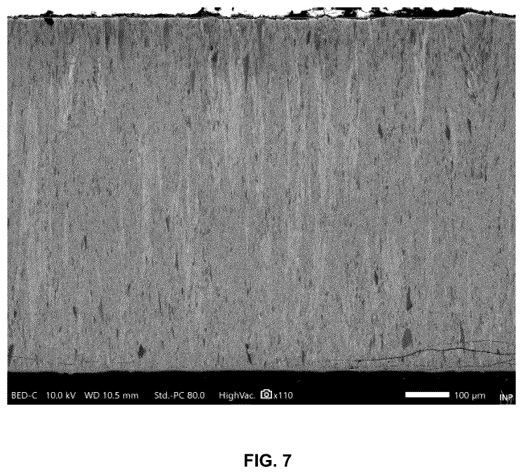

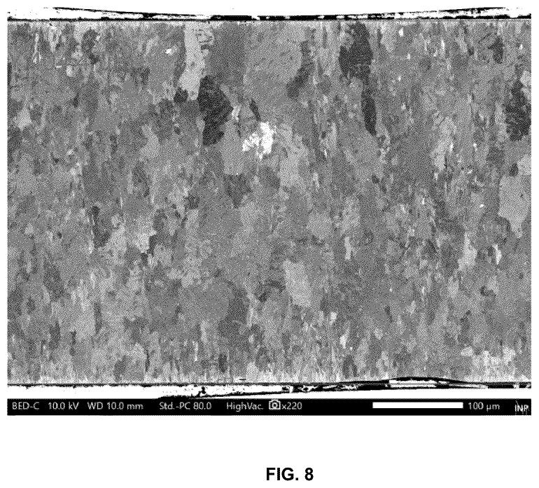

The coalescence of neighbouring grains also significantly changes their morphology, since CVD growth tends to be very oriented along the direction of the thickness of the raw disc, with grains before heat treatment extending mainly along the Z axis visible in FIG. 7. As visible in FIG. 8, the heat treatment leads to the appearance of grains with very different morphology. In particular, the raw disc or support substrate comprises grains having an aspect ratio, defined as being the ratio between, in the numerator, the length of the grain along the Z axis and, in the denominator, the diameter of the grain in one direction perpendicular to the Z axis, less than or equal to 10, in particular less than or equal to 5, in particular less than or equal to 3. In particular, at least 5% of the grains have such an aspect ratio.

The heat-treated raw blank can then be ground to obtain an intermediate blank; this is the subject of the third step mentioned above. This grinding has two goals: firstly, it represents a necessary step to be able to polish the surface, in order to prepare it for the deposition of a layer of m-SiC, this deposition being able to be carried out in particular by a layer transfer technique. Secondly, grinding (which typically proceeds by successive removal of material on both sides of the raw blank) makes it possible to obtain a p-SiC slice at the final thickness, which has high flatness.

The intermediate blank advantageously has a thickness close to the final thickness targeted for the p-SiC wafer ready to receive the m-SiC layer (such a polished wafer being commonly called a “wafer”), which allows it by the following being used, on this m-SiC face, as a substrate for the deposition of microelectronic circuits according to the usual manufacturing techniques in this field.

More precisely, the thickness of said intermediate blank is advantageously less than 550 μm, preferably less than 500 μm, more preferably less than 450 μm, and even more preferably comprised between 355 μm and 420 μm.

Such an intermediate blank, and in the same way a polished wafer, have all the crystallographic characteristics indicated above, namely a preferential crystalline orientation which is characterized in that on each of its faces: (i) its texture coefficient C₄₂₂ is less than 40%, and (ii) its texture coefficient C₂₂₀+C₂₀₀+C₄₀₀ is greater than 50%, and preferably greater than 80%.

Preferably, the contribution C₂₀₀+C₄₀₀ is greater than 1%, more preferably greater than 2%, and even more preferably greater than 5%.

Advantageously, said polished wafer has on each of its two faces a texture coefficient C₄₂₂ which is less than 20%, preferably less than 15%, and even more preferably less than 10%.

According to one aspect of the invention, the method according to the invention makes it possible to obtain a polycrystalline SiC plate which has an electrical resistivity less than 10 mOhm·cm, preferably less than 5 mOhm·cm, and even more preferably less than 3 mOhm·cm.

According to another aspect of the invention, the method according to the invention makes it possible to obtain a polycrystalline SiC plate which is doped with nitrogen with a nitrogen content, measured by secondary ion mass spectroscopy, greater than 5×10¹⁹ atoms/cm³, preferably greater than 1×10²⁰ atoms/cm³, and even more preferably greater than 1.5×10²⁰ atoms/cm³.

Without wishing to be bound by this theory, the inventors believe that the heat treatment of the plate allows, among other things, better diffusion of the nitrogen dopant, and leads to an incorporation of nitrogen atoms into the crystallographic network which is electronically more efficient.

In a first advantageous embodiment, such a p-SiC plate, which can typically be an intermediate blank or a polished wafer, has a diameter of between 140 mm and 165 mm, a thickness of between 350 μm and 450 μm and a deformation characterized by a Warp less than 50 μm, preferably less than 40 μm and even more preferably less than 30 μm. Preferably, such a plate has a thickness comprised between 350 μm and 400 μm.

In a second advantageous embodiment, such a p-SiC plate, which can typically be an intermediate blank or a polished wafer, has a diameter of between 185 mm and 210 mm, a thickness of between 500 μm and 650 μm, and a deformation characterized by a Warp less than 70 μm, preferably less than 50 μm and even more preferably less than 40 μm. Preferably, such a plate has a thickness comprised between 500 μm and 600 μm.

### EXAMPLES

Examples 1 to 4 illustrate certain aspects of the invention, but do not limit its scope.

In these examples, diffraction peaks were collected by an X-ray diffractometer of the PANalytical X'Pert PRO MPD type by the θ-2θ method over an angle range from 10° to 135° (2θ scale). Over this range for SiC 3C the ten diffraction peaks appearing in table 1 were taken into account, classified according to increasing Miller indices (hkl); these diffraction peaks are characteristic of beta-type SiC.

TABLE 1
Diffraction peaks taken into account

| | | Theoretical intensity [%] |
|---|---|---|
| | | (Source ICDD, SiC-3C, |
| hkl | 2θ peak position [°] | Data set 00-029-1129) |
| 111 | [34,940°-36,345°] | 100 |
| 200 | [41,230°-41,584°] | 23 |
| 220 | [59,494°-60,452°] | 57 |
| 311 | [71,167°-72,348°] | 48 |
| 222 | [75,303°-75,749°] | 10 |
| 400 | [89,575°-90,298°] | 12 |
| 331 | [100,250°-101,537°] | 25 |
| 420 | [104,045°-104,885°] | 13 |
| 422 | [119,276°-120,418°] | 14 |
| 511 | [132,367°-134,021°] | 15 |

A texture coefficient Cₕₖₗ (for N=10 peaks) is calculated from the intensity of the peak Iₙₖₗ proportional to the area under the peak of the sample and the theoretical intensity I_{0 hkl} of a powder which can be obtained from theoretical % published by the ICDD (International Centre for Diffraction Data).

$${C}_{hkl} = ( {I}_{hkl} / {I}_{0 hkl} ) / ( 1 / N \times \sum ( {I}_{hkl} / {I}_{0 hkl} ) ) .$$

The texture coefficient in this case varies over a range from 0 to 10. It can also be expressed in %. It makes it possible to quantify the average preferential orientation of the crystallites of the deposited layer relative to the normal of the sample surface.

In these examples, the carbon source and the silicon source were the same molecule, namely methyl trichlorosilane (abbreviated MTCS). The nitrogen source doping gas was NH₃. By modifying the few key parameters of the CVD process (temperature, partial pressure of the precursor, % of doping gas), it is possible to change the orientation of the deposited layer and its texture. This will have an impact on the gradient of intrinsic stresses of the deposit making it possible to obtain a Warp on the raw blank conforming to the objective.

### Example 1: Majority Oriented Coarse Grain Texture (422) Mixed with a Fine Texture of Small Oriented Grains (220)

An intermediate p-SiC blank was prepared by grinding and polishing from a raw blank obtained by a CVD process outside the invention. To prepare the raw blank, a layer of 800 μm was deposited on a graphite substrate operating at a temperature of 1 600 K, a partial pressure of 16 mbar of MTCS and a mole fraction of NH₃ of 6%.

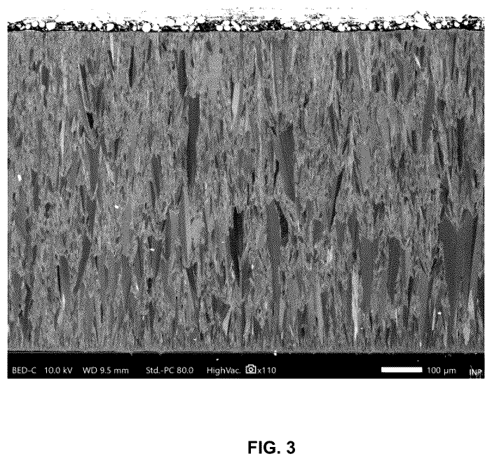

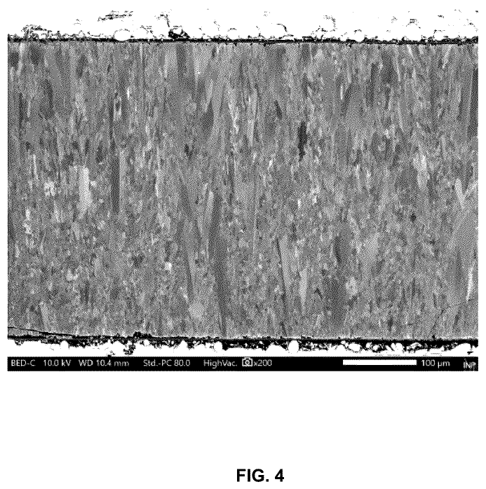

FIGS. 3 and 4 show two images obtained by scanning electron microscopy of backscattered electrons from a cross section, before (FIG. 3) and after (FIG. 4) heat treatment at 2 000° C. On each of these figures the white bar indicates a length of 100 μm.

Before the heat treatment according to the invention, during which the blank was maintained at flat on a flat surface, the intermediate blank shows an orientation characterized by a dominant texture coefficient C₄₂₂, presenting very large grains oriented according to the texture coefficients collected below:

$${C}_{111} + {C}_{222} + {C}_{511} = 20 \% ; {C}_{220} = 7 \% ; {C}_{422} = 54 \% .$$

We observe in FIG. 3 very large grains oriented mainly (422) or (111) in a minority, conical in shape with diameters of up to 100 μm. A few small grains (220) less than 10 μm in size are a very small minority. We observe in FIG. 3 a continuous growth in grain diameter over the first 500 microns. This growth in grain size can be evaluated for each ordinate of the mark by counting the number of intersections of a horizontal line of constant ordinate with the grain boundaries on the EBSD image.

After a heat treatment according to the invention, during which the blank was held flat on a flat surface, we do not observe a significant evolution of the microstructure and the orientation of the grains.

On the raw blank before heat treatment, the deposit obtained contains a nitrogen concentration measured by SIMS (Secondary Ion Mass Spectroscopy) of 6.8×1020 nitrogen atoms per cm³ and an electrical resistivity measured at 0.9 mOhm·cm by the 4-point method, well below the target upper limit. The deformation measured on the raw wafer is very significant with a Warp of 580 μm. The thermal conductivity of the layer has been deduced by measuring thermal diffusivity using the laser flash method. A value of 130 W/m/K has been obtained, which is below the target objective. After heat treatment, the Warp and internal stresses remain high, and the electrical resistivity and thermal conductivity practically do not change.

This example shows that the heat treatment according to the invention does not lead to an improvement in the crystallographic and physical properties when the initial texture of the blank before heat treatment has a dominant C₄₂₂ texture. A significant number of plates were produced according to this example; on a total of 16 discs produced, the average deformation is 630 μm with a standard deviation of 153 μm. We conclude that it will not be possible to produce a p-SiC wafer by grinding from a raw disk with a thickness of less than 1 000 μm.

After several depositions according to these conditions, the observed texture remains preferentially oriented (422) with the texture coefficient C₄₂₂>50% and C₁₁₁+C₂₂₂+C₅₁₁>15% and C₂₂₀<10%.

### Example 2

An intermediate p-SiC blank was prepared by grinding and polishing from a raw blank obtained by a CVD process outside the invention. To prepare the raw blank, a layer of p-SiC with a thickness of approximately 800 μm was deposited on a flat graphite substrate by operating the CVD reactor at a temperature of 1 530 K, a partial pressure of 12 mbar of MTCS and a mole fraction of NH₃ of 5%.

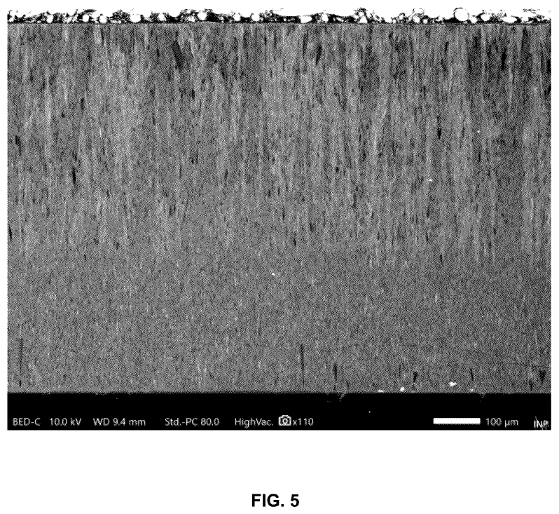

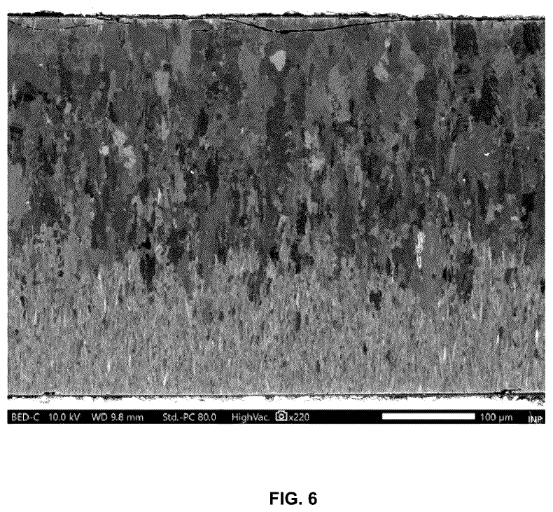

FIGS. 5 and 6 show two images obtained by scanning electron microscopy of backscattered electrons of a cross section, before (see FIG. 5) and after (see FIG. 6) a heat treatment at 2 000° C. according to the invention, during which the blank was held flat on a flat surface. In each of these figures the white bar indicates a length of 100 μm.

A preferentially oriented texturing (220) was observed with the following texture coefficients: C₁₁₁+C₂₂₂+C₅₁₁=2%; C₂₂₀=90%; C₄₂₂=3%.

The layer contained a nitrogen concentration, measured by SIMS, of 2.7×10²⁰ nitrogen atoms per cm³, and had an electrical resistivity of 10 mOhm·cm, measured by the four-point method. The thermal conductivity, deduced from a thermal diffusivity measurement using the laser flash method, was 130 W/m/K. This value was below the target objective; the tree texture no longer seems to promote good thermal conductivity, being barely visible on the lower part of the section.

The deformation measured on the raw blank without heat treatment is low. On a total of 16 plates produced, the average deformation was 160 μm, with a standard deviation of 85 μm. This would allow wafers for p-SiC wafers to be manufactured from a disk raw material with a thickness of less than 1,000 μm at a reasonable cost.

However, the texture is inhomogeneous in depth at the start of growth, which is accounted for when the face of the plate which was in contact with the graphite surface of the growth substrate is characterized by X-ray diffraction when carrying out successive grinding stages: the substrate side face is predominantly oriented (111)+(222)+(511) over a very significant depth, which does not allow grinding to be used to remove this inhomogeneous zone in depth under reasonable economic conditions.

After heat treatment on the intermediate blank with a thickness of approximately 400 μm (see the FIG. 6), a very significant growth in grain size was also observed on the upper part of the preferentially oriented section (220). On the other hand, the lower part of the section representing the substrate face, always preferentially oriented (111)+(222)+(511), does not show any change in the size of its grains due to the heat treatment.

This observed grain size inhomogeneity is highly detrimental. One observes that the Warp of this intermediate blank degrades beyond 250 μm in the most cases, making it impossible to obtain a wafer presenting a Warp conforming to the objective.

### Example 3: Oriented Fine-Grain Texture (220)

An intermediate p-SiC blank was prepared by grinding and polishing from a raw blank obtained by a CVD process according to the invention. To prepare the blank, a layer of 800 μm as deposited on a graphite substrate, operating at a temperature of 1 550 K, a partial pressure of 15 mbar of MTCS and a mole fraction of NH₃ of 4%. The orientation observed before said heat treatment is a texturing oriented preferably (220) with texture coefficients gathered below:

$${C}_{111} + {C}_{222} + {C}_{511} = 2 \% ; {C}_{220} = 91 \% ; {C}_{422} = 4 \%$$

The C₂₀₀+C₄₀₀ contribution was zero. The layer contained a concentration of nitrogen measured by SIMS of 1.8×10²⁰ atoms of nitrogen per cm³ and an electrical resistivity measured at 10 mOhm·cm by the four-point method. The thermal conductivity of the layer is deduced by a thermal diffusivity measurement using the laser flash method. A value of 240 W/m/K was obtained, which is above the desired objective. Despite the small grains, the tree-like texture seems promote good thermal conductivity, despite high doping.

The deformation measured on the raw blank before annealing is also very good. On a total of 16 discs produced, the average deformation is 210 μm with a standard deviation of 82 μm. This makes it possible to produce p-SiC wafers by grinding from a raw disk thickness less than 1 000 μm at a reasonable cost.

After several depositions according to these conditions, the texture observed is highly oriented (220) with the texture coefficient C₂₂₀>90% and C₄₂₂<10%.

An intermediate p-SiC blank was prepared by grinding and polishing from a raw blank obtained by a CVD process according to the invention. FIGS. 7 and 8 show images obtained by scanning electron microscopy of backscattered electrons of a cross section, of the raw blank before heat treatment (see FIG. 7) and the intermediate blank after (see FIG. 8) heat treatment at 2 000° C. On each of these figures the white bar indicates a length of 100 μm.

The raw blank showed a dominant C₂₂₀ texture coefficient, with a component (111) significant close to the interface with the graphitic surface on which the blank has been deposited. This thickness of the raw blank rich in C₁₁₁ texture was removed by grinding during the manufacture of the intermediate blank.

After a heat treatment according to the invention, during which the blank was maintained flat on a flat surface, a significant evolution of the microstructure and the orientation of the grains was observed: the small grains of orientation (220) tend to coalesce and a mixed orientation (111)+(220)+(200) is obtained. Few small orientation grains are observed (111). The C₂₀₀+C₄₀₀ contribution appears after heat treatment; it is equal to 5% after heat treatment.

The Warp decreases thanks to the heat treatment and is located within the specifications loads, which coincides with a more uniform distribution of grain size in the thickness of the intermediate blank. The electrical resistivity decreases until it reaches 1.2 mOhm·cm and the thermal conductivity increases to 270 W/m/K. This example conforms to the invention.

### Example 4: Verification of the Crystallographic Structure

The crystallographic structure of a plate referenced BJ2-22-19-3G was compared before and after heat treatment according to the invention (in this case at approximately 2 000° C. for a duration between approximately and approximately 1 hour and approximately 10 hours). This plate relates to Example 3.

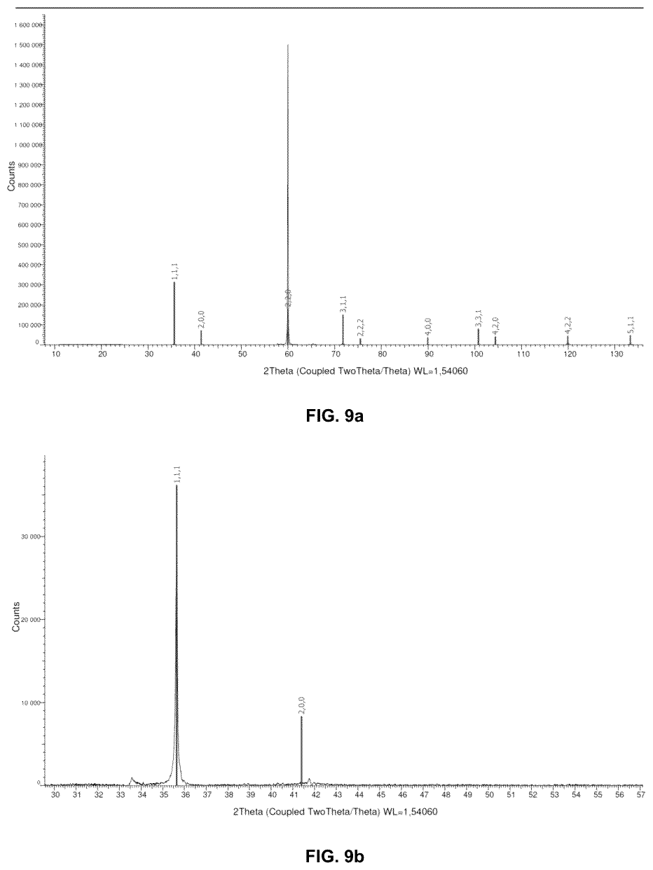

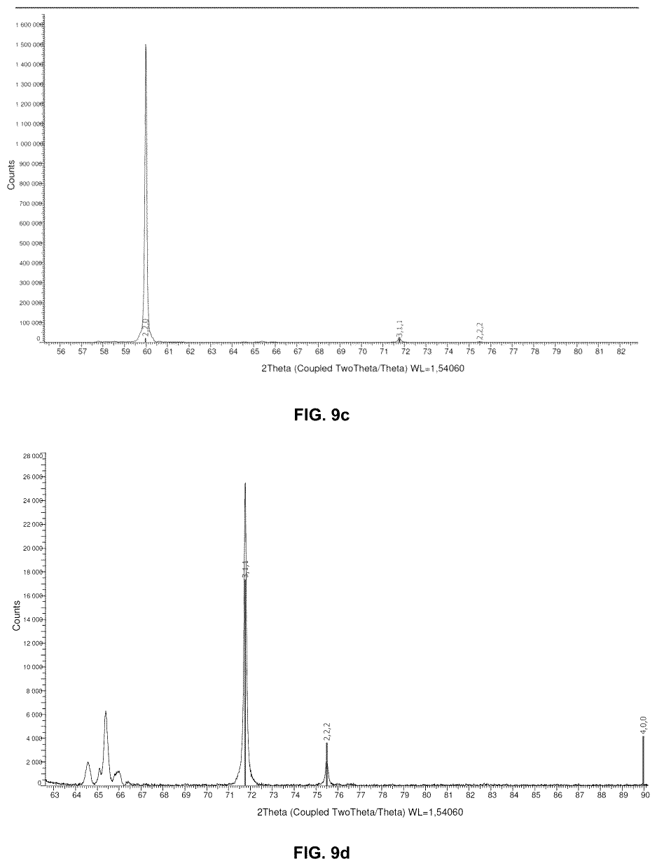

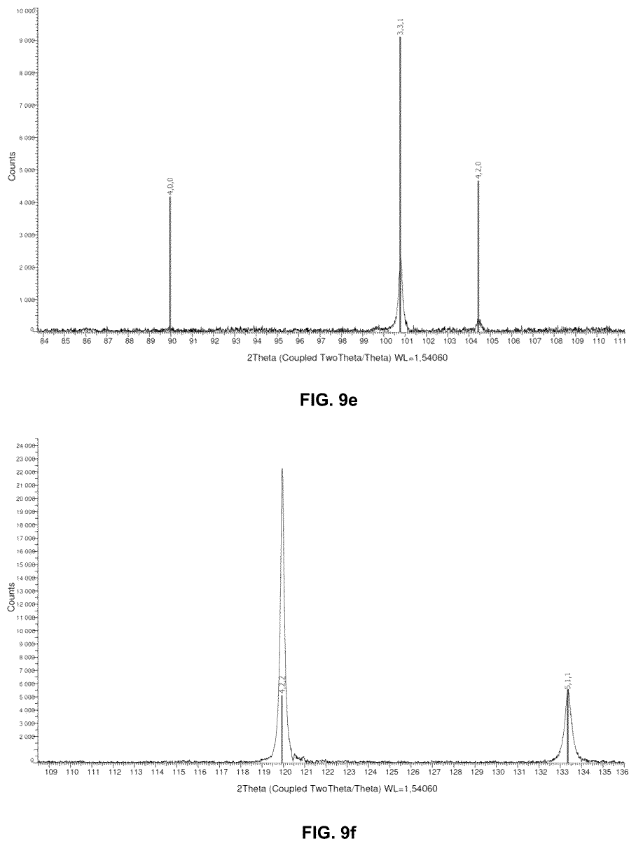

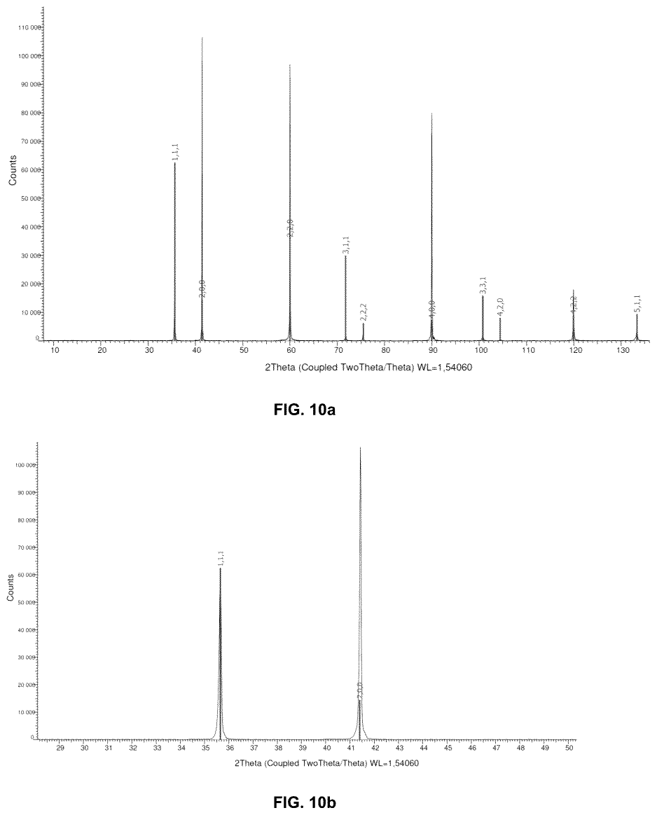

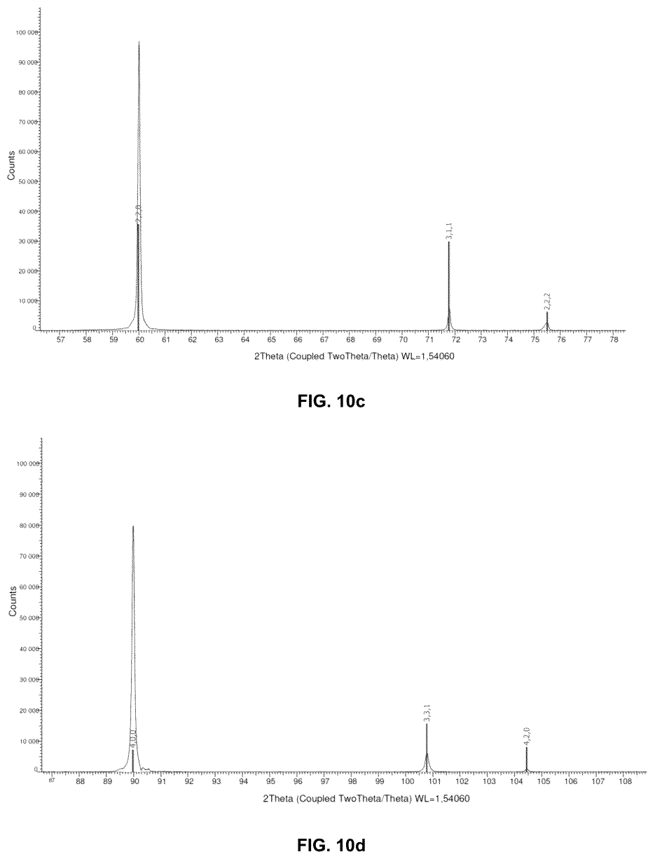

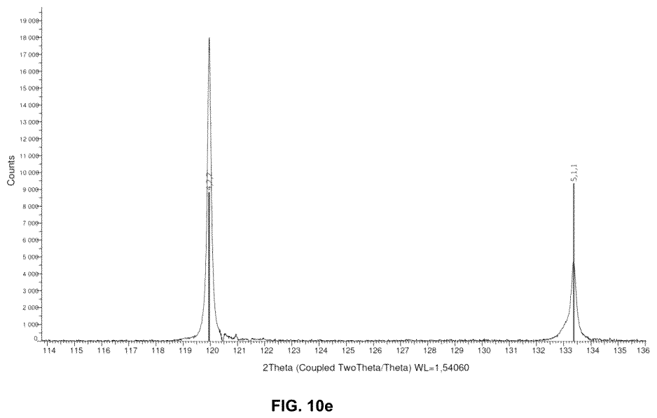

FIGS. 9a to 9f show the diffractogram before heat treatment, FIGS. 10a to 10e after heat treatment. In each of these figures, the diffractogram is first shown in its entire width, see FIGS. 9a to 9f and FIGS. 10a to 10e, then by segment of 2theta using a scale in intensity factor adapted to the different peaks, which can be different from a segment of 2theta to the other. The vertical bars represent the indexing of the peaks.

It is noted in the plate before heat treatment the presence of two peaks of low intensity representing stacking faults of the 3C polytype. These peaks (around 33.5° to 33.9°—see [FIG. 9b] and 65.3° with two satellites around 64.6° and 65.9°—(see FIG. 9d) disappear after heat treatment. No peak characteristic of alpha type SiC is seen, neither before nor after heat treatment.

1-24. (canceled)

25. A beta-type polycrystalline SiC plate with a preferential crystalline orientation, the beta-type polycrystalline SiC plate comprising:
a plate structure having on each face thereof: (i) its texture coefficient C₄₂₂ is less than 40%, and (ii) a texture coefficient C₂₂₀+C₂₀₀+C₄₀₀ greater than 80%.

26. The beta-type polycrystalline SiC plate of claim 25, wherein the plate structure has an electrical resistivity of less than 3 mOhm·cm.

27. The beta-type polycrystalline SiC plate of claim 25, wherein the plate structure is doped with nitrogen with a nitrogen level, measured by secondary ions mass spectroscopy, of greater than 1.5×10²⁰ atoms/cm³.

28. The beta-type polycrystalline SiC plate of claim 25, wherein the plate structure has on each face thereof a texture coefficient C₄₂₂ of less than 10%.

29. The beta-type polycrystalline SiC plate of claim 25, wherein the plate structure:
is doped with nitrogen with a nitrogen level, measured by mass spectroscopy of secondary ions, of greater than 5×10¹⁹ atoms/cm³,
has an electrical resistivity lower than 5 mOhm·cm and a preferential crystal orientation,
has on each face thereof: (i) a texture coefficient C₄₂₂ of less than 20%, and (ii) a texture coefficient C₂₂₀+C₂₀₀+C₄₀₀ of greater than 80%.

30. The beta-type polycrystalline SiC plate of claim 25, wherein:
the plate structure comprises a raw blank formed from a vapor phase deposition process and which has undergone at least one heat treatment step at a temperature between 1950° C. and 2150° C. in which the plate structure is held flat on a flat surface, and
before or after the heat treatment, a material thickness of at least 100 μm is removed from the raw blank, at least on its face which was in contact with a growth substrate.

31. The beta-type polycrystalline SiC plate of claim 30, wherein the plate structure comprises an intermediate blank for manufacture of a wafer obtained by grinding of the raw blank.

32. The beta-type polycrystalline SiC plate of claim 31, wherein the plate structure has a diameter between 140 mm and 165 mm, a thickness between 350 μm and 450 μm, and a Warp deformation of less than 30 μm.

33. The beta-type polycrystalline SiC plate of claim 31, wherein the plate structure has a diameter of between 185 mm and 210 mm, a thickness between 500 μm and 600 μm, and a Warp deformation of less than 40 μm.

34. The beta-type polycrystalline SiC plate of claim 25, wherein the contribution C₂₀₀+_{C400} is greater than 5%.

35. The beta-type polycrystalline SiC plate of claim 25, wherein the plate structure has a thermal conductivity greater than 270 W/(m·K).

36. The beta-type polycrystalline SiC plate of claim 25, wherein the plate structure has:
an electrical resistivity less than 3 mOhm·cm,
a doping level, measured by SIMS, greater than 1.5×10²⁰ atoms/cm³,
on each side thereof, a C₂₀₀+C₄₀₀ contribution greater than 5%, and
a thermal conductivity greater than 270 W/(m·K).

37. The beta-type polycrystalline SiC plate of claim 25, wherein the plate structure has:
an electrical resistivity less than 3 mOhm·cm,
a doping level, measured by SIMS, greater than 1.5×10²⁰ atoms/cm³,
on each side thereof, a C₂₀₀+C₄₀₀ contribution greater than 5%, and
a thermal conductivity greater than 270 W/(m·K).

38. A method for manufacturing a polycrystalline SiC plate, comprising:
forming a polycrystalline SiC layer on a graphite surface of a substrate by chemical vapor deposition (CVD), the CVD including a mixture of gases introduced into a heated enclosure to create a gas mixture comprising: at least one gaseous silicon and/or carbon precursor, at least one doping gas comprising at least one nitrogen atom, and a carrier gas, wherein the gas mixture decomposes on the graphite surface to form the polycrystalline SiC layer, wherein the temperature in the heated enclosure is between 1450 K and 1650 K and the total partial pressure of said gaseous precursors is less than 300 mbar; and
supporting the substrate on a flat surface while performing at least one heat treatment step of the polycrystalline SiC layer at a temperature between 1950° C. and 2150° C.

39. The method of claim 38, wherein the at least one doping gas is selected from the group formed by NH₃, N₂H₄, N₂, H₂NCH₃.

40. The method of claim 38, wherein the at least one doping gas is present in said heated enclosure at a concentration to conduct in the polycrystalline SiC plate to a level of nitrogen or phosphorus, measured by secondary ion mass spectroscopy, greater than 1.5×10²⁰ atoms/cm³.

41. The method of claim 38, further comprising clearing the substrate, said plate has been cleared, before the heat treatment, at least on the side which was in contact with a growth substrate, with a material thickness of at least 100 μm.

42. The method of claim 38, further comprising clearing the substrate, said plate has been cleared, after the heat treatment, at least on the side which was in contact with a growth substrate, with a material thickness of at least 100 μm.
